(19) United States
(12) Patent Application Publication
(10) Pub. No.: US 2025/0048834 A1
(43) Pub. Date: Feb. 6, 2025

(54) DISPLAY PANEL AND DISPLAY APPARATUS

(71) Applicant: Hubei Yangtze Industrial Innovation Center Of Advanced Display Co., Ltd., Wuhan (CN)

(72) Inventors: Lei WANG, Wuhan (CN); Jun YAN, Wuhan (CN); You GAO, Wuhan (CN)

(21) Appl. No.: 18/922,188

(22) Filed: Oct. 21, 2024

(30) Foreign Application Priority Data
Aug. 16, 2024 (CN) 202411133305.X

(51) Int. Cl. H10K 59/121; H10K 59/122; H10K 59/80

(52) U.S. Cl. CPC H10K 59/121; H10K 59/122; H10K 59/80518; H10K 59/80524; H10K 59/873; H10K 59/8792

(57) ABSTRACT

A display panel and a display apparatus are provided. The display panel includes: a substrate; light-emitting elements located at a side of the substrate; an encapsulation layer located at a side of the light-emitting elements away from the substrate; a reflection control layer located at a side of the encapsulation layer away from the light-emitting elements; and a barrier layer located at a side of the reflection control layer away from the encapsulation layer, wherein the barrier layer is in contact with the reflection control layer. The present disclosure uses the reflection control layer to reduce the reflectivity of the display panel, thereby reducing the manufacturing process and reducing the manufacturing cost. The barrier layer can block the dye in the reflection control layer from migrating to the side away from the substrate, thereby achieving stability of the anti-reflection performance of the reflection control layer and improving display quality.

### CROSS-REFERENCE TO RELATED APPLICATION

The present application claims priority to Chinese Patent Application No. 202411133305.X, filed on Aug. 16, 2024, the content of which is incorporated herein by reference in its entirety.

### TECHNICAL FIELD

The present disclosure relates to the field of display technologies, and in particular, to a display panel and a display apparatus.

### BACKGROUND

Organic light-emitting diode (OLED) display screens have advantages of being light and thin, high brightness, low power consumption, fast response, high definition, good flexibility, and high luminous efficiency, which can meet new requirements of consumers on display technologies. At present, one of key factors affecting the display quality is reflection situation of ambient light by the display screen.

### SUMMARY

In an aspect, the present disclosure provides a display panel. The display panel includes: a substrate; light-emitting elements located at a side of the substrate; an encapsulation layer located at a side of the light-emitting elements away from the substrate; a reflection control layer located at a side of the encapsulation layer away from the light-emitting elements; and a barrier layer located at a side of the reflection control layer away from the encapsulation layer. The barrier layer is in contact with the reflection control layer.

In another aspect, the present disclosure provides a display apparatus. The display apparatus includes a display panel. The display panel includes: a substrate; light-emitting elements located at a side of the substrate; an encapsulation layer located at a side of the light-emitting elements away from the substrate; a reflection control layer located at a side of the encapsulation layer away from the light-emitting elements; and a barrier layer located at a side of the reflection control layer away from the encapsulation layer. The barrier layer is in contact with the reflection control layer.

### BRIEF DESCRIPTION OF DRAWINGS

The foregoing and other features of the present disclosure will become apparent to those skilled in the art to which the present disclosure relates upon reading the following description with reference to the accompanying drawings, in which:

FIG. 1 is a schematic diagram of a display panel according to some embodiments of the present disclosure;

FIG. 2 is a cross-sectional view at a line A-A′ shown in FIG. 1 according to some embodiments of the present disclosure;

FIG. 3 is a cross-sectional view at a line A-A′ shown in FIG. 1 according to some embodiments of the present disclosure;

FIG. 4 is a cross-sectional view at a line A-A′ shown in FIG. 1 according to some embodiments of the present disclosure; and

FIG. 5 is a schematic diagram of a display apparatus according to some embodiments of the present disclosure.

### DESCRIPTION OF EMBODIMENTS

In order to more clearly illustrate objectives, technical solutions, and advantages of the embodiments of the present disclosure, the technical solutions in the embodiments of the present disclosure are clearly and completely described in details with reference to the accompanying drawings. The described embodiments are merely part of the embodiments of the present disclosure rather than all of the embodiments. All other embodiments obtained by those skilled in the art based on the embodiments of the present disclosure without paying creative labor shall fall into the protection scope of the present disclosure.

The terms used in the embodiments of the present disclosure are merely for the purpose of describing specific embodiment, rather than limiting the present disclosure. The terms “a”, “an”, “the” and “said” in a singular form in the embodiments of the present disclosure and the attached claims are also intended to include plural forms thereof, unless noted otherwise.

It should be understood that although the terms ‘first’ and ‘second’ may be used in the present disclosure to describe XXs, these XXs should not be limited to these terms. These terms are used only to distinguish the XXs from each other. For example, without departing from the scope of the embodiments of the present disclosure, a first XX may also be referred to as a second XX. Similarly, the second XX may also be referred to as the first XX.

In a structure of a display panel of the related art, a color filter layer is formed above a light-emitting element as an anti-reflection layer, utilizing the color filter layer to reduce the reflection of ambient light on the display panel. This technique requires fabricating a red filter unit above a red light-emitting element, a green filter unit above a green light-emitting element, and a blue filter unit above a blue light-emitting element. Different color filter units need to be manufactured using a photolithography process, respectively, resulting in complex process and high manufacturing cost of the anti-reflection layer.

In order to solve the problems in the related art, the present disclosure provides a display panel, which uses a reflection control layer instead of a color filter layer to reduce the reflectivity of the display panel, and the reflection control layer on light-emitting elements of different colors does not need to be arranged differently, reducing the manufacturing process of the anti-reflection layer and reducing the manufacturing cost. In addition, the barrier layer is made at a side of the reflection control layer away from a substrate, which can block the dye in the reflection control layer from migrating to a side away from the substrate, thereby achieving stable performance of the reflection control layer.

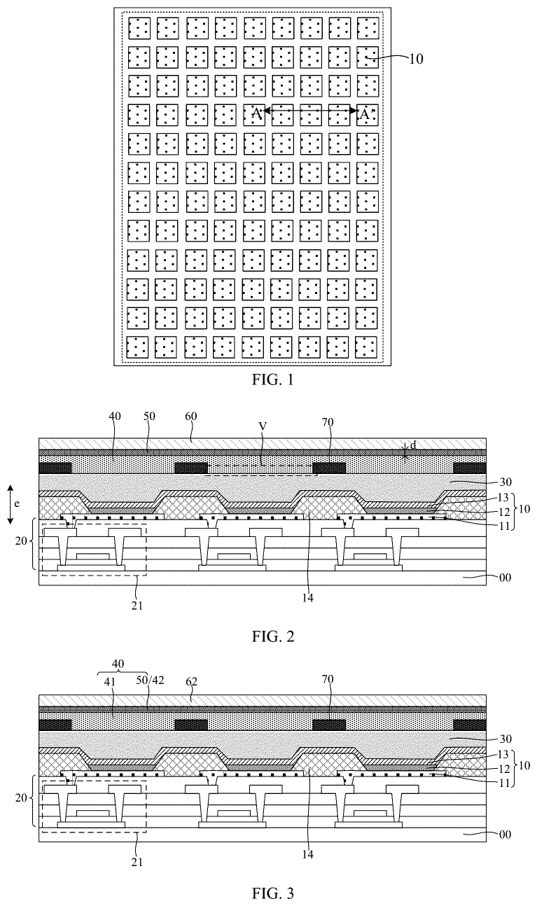

FIG. 1 is a schematic diagram of a display panel according to some embodiments of the present disclosure, and FIG. 2 is a cross-sectional view at a line A-A′ shown in FIG. 1. FIG. 1 schematically shows multiple light-emitting elements 10 on the display panel, and multiple light-emitting elements 10 at least include a red light-emitting element, a green light-emitting element and a blue light-emitting element. In some embodiments, the light-emitting elements 10 may further include a white light-emitting element. The shape and arrangement of the light-emitting elements 10 shown in FIG. 1 are merely illustrative and are not intended to limit the present disclosure. The light-emitting elements 10 may be an organic light-emitting diode or an inorganic light-emitting diode.

As shown in FIG. 2, the light-emitting elements 10 are fabricated on the substrate 00. A pixel definition layer 14 is spaced between adjacent light-emitting elements 10. The substrate 00 may be a flexible substrate or a rigid substrate. The flexible substrate may be formed of a polymer material such as polyimide (PI), polycarbonate (PC), polyethersulfone (PES), polyethylene terephthalate (PET), polyethylene naphthalate (PEN), polyarylate (PAR) or fiberglass reinforced plastic (FRP). The flexible substrate may be transparent, translucent, or opaque. The rigid substrate may include, for example, a quartz substrate, a glass substrate, etc. The light-emitting elements 10 include a first electrode 11, a light-emitting layer 12, and a second electrode 13. In some embodiments of the present disclosure, the first electrode 11 is an anode, and the second electrode 13 is a cathode. The first electrode 11 is a patterned structure, and the second electrodes 13 of multiple light-emitting elements 10 are connected to one another to form a common electrode. The first electrode 11 is a reflective electrode, and the first electrode 11 includes a reflective layer and a transparent layer. The reflective layer may be formed of Ag, Mg, Al, Pt, Pd, Au, Ni, Nd, Ir, Cr or a mixture thereof. The transparent layer is formed by forming Indium tin oxide (ITO), indium zinc oxide (IZO), zinc oxide (ZnO) or indium oxide (In₂O₃) on the reflective layer. The second electrode 13 is a transparent electrode, and a compound with a small work function such as lithium (Li), calcium (Ca), lithium fluoride/calcium (LiF/Ca), lithium fluoride/aluminum (LiF/Al), aluminum (Al), magnesium (Mg), or a combination thereof may be initially deposited on the light-emitting layer 12 by evaporation, and a transparent electrode forming material such as ITO, IZO, ZnO, or In₂O₃ may be deposited on the compound.

A driving layer 20 is provided between the substrate 00 and the light-emitting element 10, and a pixel circuit 21 is provided in the driving layer 20. The pixel circuit 21 is connected to the first electrode 11 of the light-emitting element 10. The structure of the pixel circuit 21 may be any structure in the prior art. For example, the pixel circuit 21 includes a driving transistor for generating a driving current. Only one transistor in the pixel circuit 21 is shown schematically in FIG. 2.

An encapsulation layer 30 is provided at a side of the light-emitting element 10 away from the substrate 00, and the encapsulation layer 30 is configured to isolate corrosion of water and oxygen on the light-emitting element 10 in order to increase a service life of the light-emitting element 10. In some embodiments of the present disclosure, the encapsulation layer 30 includes at least one inorganic encapsulation layer and at least one organic encapsulation layer. For example, the encapsulation layer 30 includes a first inorganic encapsulation layer, an organic encapsulation layer, and a second inorganic encapsulation layer, and the organic encapsulation layer is located between the first inorganic encapsulation layer and the second inorganic encapsulation layer.

A reflection control layer 40 is provided at a side of the encapsulation layer 30 away from the light-emitting element 10. The reflection control layer 40 is an anti-reflection layer for reducing the reflection of ambient light by the display panel. The reflection control layer 40 may selectively absorb some wavelength bands of light in the ambient light emitted to the display panel or absorb some wavelength bands of light in the light reflected from the inside of the display panel. For example, the light-emitting element 10 includes the red light-emitting element, the green light-emitting element and the blue light-emitting element, and the reflection control layer 40 can absorb light in a wavelength band deviating from an emission wavelength range of the red light-emitting element, the green light-emitting element and the blue light-emitting element, thereby reducing the reflection of ambient light by the display panel while avoiding the reduction of display brightness. The material of the reflection control layer 40 includes at least dye. The reflection control layer 40 is a whole film layer, or in other words, the reflection control layers 40 overlapping with the light-emitting elements of different colors are connected to one another as a whole. The reflection control layer 40 may be manufactured using a film-forming process commonly used in manufacturing the display panel, without different settings for the light-emitting elements of different colors, reducing the manufacturing processes and the manufacturing cost.

A barrier layer 50 is provided at a side of the reflection control layer 40 away from the encapsulation layer 30, and the barrier layer 50 is in contact with the reflection control layer 40. In some embodiments of the present disclosure, a touch layer may be further provided between the reflection control layer 40 and the encapsulation layer 30, and the touch detection function of the display panel may be implemented by using the touch layer.

The display panel provided by the embodiments of the present disclosure is provided with the reflection control layer 40 and the barrier layer 50, and the barrier layer 50 is located at a side of the reflection control layer 40 adjacent to the substrate 00. The reflection control layer 40 can replace the color filter layer in the related art to reduce the reflectivity of the display panel. The reflection control layer 40 can be configured as a whole layer, and the reflection control layer 40 on the light-emitting elements 10 of different colors does not need to be arranged differently, reducing the manufacturing process of the display panel and reducing the manufacturing cost. In addition, the barrier layer 50 can block the dye in the reflection control layer 40 from migrating to the side away from the substrate 00, thereby achieving the stability of the anti-reflection performance of the reflection control layer 40, and avoiding failure of the reflection control layer 40 caused by optical abnormality due to migration of the dye.

As shown in FIG. 2, the display panel includes a protective layer 60 located at a side of the barrier layer 50 away from the reflection control layer 40. The material of the protective layer 60 includes at least one of polyethylene terephthalate (PET), polypropylene (PP), a polyepoxy material, a cyclic olefin polymer (COP), a cyclic olefin copolymer (COC), a copolymer of a polycarbonate resin and a cyclic olefin copolymer, polymethyl methacrylate (PMMA), polycarbonate (PC), polyvinyl chloride, triacetyl cellulose, and polyethylene naphthalate. In application, the dye in the reflection control layer 40 has a risk of migrating into the protective layer 60, and the migration of the dye may cause optical abnormality, resulting in a performance failure of the reflection control layer 40 to reduce the reflectivity of the display panel. According to the display panel provided by the embodiments of the present disclosure, the barrier layer 50 is arranged between the reflection control layer 40 and the protective layer 60, and the barrier layer 50 can block the dye in the reflection control layer 40 from migrating to the protective layer 60, thereby achieving the stability of the anti-reflection performance of the reflection control layer 40, avoiding failure of the reflection control layer 40 caused by optical abnormality due to migration of the dye, and achieving the display quality.

In some embodiments of the present disclosure, as shown in FIG. 2, a thickness of the barrier layer 50 is d, where d≤5000 Å. In some embodiments of the present disclosure, the thickness of the barrier layer 50 is limited, and the barrier layer 50 is not required to be too thick, because if the barrier layer 50 is too thick, it will not only affect the thickness of the entire display panel, but also increase the process difficulty of manufacturing the barrier layer 50. In some embodiments of the present disclosure, the thickness of the barrier layer 50 is not greater than 5000 Å, so that the barrier layer 50 can meet the requirements of blocking the migration of the dye. In addition, the barrier layer 50 can be manufactured by a conventional film-forming process in the manufacturing of the display panel, and the process is simple.

In some embodiments of the present disclosure, when a test frequency is 1 KMHz, a dielectric constant & of the barrier layer 50 is greater than or equal to 5. In some embodiments of the present disclosure, the barrier layer 50 has a relatively large dielectric constant, so that the barrier layer 50 can have a relatively high capacitance storage capability, and thus the interaction between the barrier layer 50 and the peripheral film layer is relatively weak. In this way, the effect between the barrier layer 50 and the dye molecules in the reflection control layer 40 can be reduced, and the barrier layer 50 is configured to block the dye in the reflection control layer 40 from migrating to the side away from the substrate 00, thereby achieving the stability of the anti-reflection performance of the reflection control layer 40.

In some embodiments of the present disclosure, a material of the reflection control layer 40 includes at least a dye and a base material. The dye includes one or more of a tetraazaporphyrin-based compound, a porphyrin-based compound, a metal porphyrin-based compound, an oxazine-based compound, a squarylium-based compound, a triarylmethane-based compound, a polymethine-based compound, a tetra-quinone-based compound, a phthalocyanine-based compound, an azo-based compound, a perylene-based compound, a xanthene-based compound, a diammonium-based compound, a dipyrrolidene-based compound, and a cyanine-based compound. The reflection control layer 40 made of the above dye selectively absorbs some wavelength bands of light in the ambient light emitted to the display panel or absorbs some wavelength bands of light in the light reflected from the inside of the display panel, thereby reducing the reflection of the ambient light by the display panel and improving the display effect of the display panel.

The base material includes a resin, such as an acrylic-based resin or a urethane-based resin. In some embodiments of the present disclosure, the material of the reflection control layer 40 includes a dye and a pigment. The dye and the pigment cooperate to enable the reflection control layer 40 to selectively absorb some wavelength bands of light in the ambient light emitted to the display panel or absorb some wavelength bands of light in the light reflected from the inside of the display panel.

In some embodiments of the present disclosure, the dye and/or the pigment are mixed and dispersed in a resin base material, and then the reflection control layer 40 is formed using a film-forming process, so that the reflection control layer 40 can selectively absorb some wavelength bands of light in the ambient light emitted to the display panel or some wavebands of light in the light reflected from the inside of the display panel. Moreover, the reflection control layer 40 may be manufactured as a whole layer, that is, the reflection control layer 40 on the light-emitting elements of different colors does not need to be located differently, reducing the manufacturing process of the display panel and reducing the manufacturing cost.

In some embodiments of the present disclosure, the dye in the reflection control layer 40 includes a cationic dye, such as a migrating cationic dye, or a dispersing cationic dye. Since the molecular mass of the dye is relatively small, and the affinity with the resin is relatively low, a migration rate of the dye molecules is relatively large, thereby causing the problem that the dye molecules are prone to migration and cause the reflection control layer 40 to fail. For example, the cationic dye in the reflection control layer 40 easily migrates and diffuses into the protective layer 60 above, making the anti-reflection performance of the reflection control layer 40 ineffective. In some embodiments of the present disclosure, the barrier layer 50 is added between the protective layer 60 and the reflection control layer 40, and the barrier layer 50 is used to block the dye in the reflection control layer 40 from migrating to the protective layer 60, thereby achieving the stability of the anti-reflection performance of the reflection control layer 40 and improving the display quality.

In some embodiments of the present disclosure, the dye in the reflection control layer 40 includes an anionic dye. Since the anionic dye is negatively charged, it easily migrates and adsorbs on a positively charged material layer. With the design of the embodiments of the present disclosure, the barrier layer 50 is used to reduce the interaction between the barrier layer 50 and the anionic dye molecules in the reflection control layer 40, thereby preventing the anionic dye in the reflection control layer 40 from migrating to the side away from the substrate 00, achieving the stability of the anti-reflection performance of the reflection control layer 40, and avoiding failure of the reflection control layer 40 caused by optical abnormality due to migration of the dye.

In some embodiments of the present disclosure, the material of the barrier layer 50 is different from the material of the reflection control layer 40. The main function of the reflection control layer 40 is to reduce the reflection of ambient light by the display panel, and the main function of the barrier layer 50 is to block the migration of the dye molecules in the reflection control layer 40. The barrier layer 50 and the reflection control layer 40 have different functions, respectively, and respective materials of the barrier layer 50 and the reflection control layer 40 are selected based on their functional effects. The barrier layer 50 and the reflection control layer 40 are made of different materials so that the functions of the barrier layer 50 and the reflection control layer 40 are optimally exerted.

In some embodiments of the present disclosure, the material of the barrier layer 50 includes an electronegative material or an electropositive material. The electronegativity is a scale of the ability of atoms of an element to attract electrons in a compound. The greater the electronegativity, the stronger the ability of atoms to attract electrons in the compound. At the compound level, the electronegativity of its constituent elements affects the electronegativity performance of the compound, that is, the electronegativity of the compound depends on the electronegativity of the chemical element of the compound. Different compound materials may exhibit different electronegativity. In other words, electronegative materials behave to have some ability to attract electrons. Electropositive refers to a tendency of atoms or molecules to lose electrons in a chemical reaction, and the electropositive material behave to have some ability to loss electrons. When the dye in the reflection control layer 40 includes a cationic dye prone to migration, the material of the barrier layer 50 may be set to include an electronegative material or an electropositive material, so that the interaction between the barrier layer 50 and the peripheral film layer is weak, thereby reducing the effect of the barrier layer 50 and the dye molecules in the reflection control layer 40. The barrier layer 50 is located between the reflection control layer 40 and the protective layer 60, so that the barrier layer 50 can be used to block a path for the dye in the reflection control layer 40 to migrate to the protective layer 60, thereby achieving the stability of the anti-reflection performance of the reflection control layer 40 and avoiding failure of the reflection control layer 40 caused by optical abnormality due to migration of the dye.

In some embodiments of the present disclosure, if the electronegativity of the barrier layer 50 is smaller than the electronegativity of the reflection control layer 40, an electron attraction capability of the reflection control layer 40 is relatively strong, and an electron attraction capability of the barrier layer 50 is relatively weak. The interaction between the barrier layer 50 and the peripheral film layer is relatively weak, so that the effect of the barrier layer 50 and the dye molecules in the reflection control layer 40 can be reduced. When the dye in the reflection control layer 40 includes the cationic dye prone to migration, since the barrier layer 50 has a relatively weak electron attraction capability, and the cationic dye further has an electron attraction capability, manufacturing the barrier layer 50 at the reflection control layer 40 does not cause the cationic dye in the reflection control layer 40 to migrate, thereby blocking a path of dye migration in the reflection control layer 40 between the reflection control layer 40 and the protective layer 60, achieving the stability of the anti-reflection performance of the reflection control layer 40, and avoiding failure of the reflection control layer 40 caused by optical abnormality due to migration of the dye.

Since there is a certain relationship between the dielectric constant and the electronegativity, the electronegativity is one of important factors affecting the dielectric constant of the material. Atoms with high electronegativity can affect the polarization capability of the material, thereby affecting the dielectric constant of the material. The relationship between dielectric constant and the electronegativity shows that high electronegativity leads to weak polarization capability, resulting in a low dielectric constant. The electronegativity of the barrier layer 50 and the reflection control layer 40 may be characterized by the dielectric constant. In some embodiments of the present disclosure, the dielectric constant of the barrier layer 50 is greater than the dielectric constant of the reflection control layer 40, so that the electronegativity of the barrier layer 50 is smaller than the electronegativity of the reflection control layer 40, to satisfy the effect of the barrier layer 50 in blocking dye migration between the reflection control layer 40 and the protective layer 60.

In some embodiments of the present disclosure, FIG. 3 is a cross-sectional view at a line A-A′ shown in FIG. 1 according to some embodiments of the present disclosure. As shown in FIG. 3, the display panel includes a first reflection control layer 41 located at a side of the encapsulation layer 30 away from the substrate 00, and the barrier layer 50 is arranged at a side of the first reflection control layer 41 away from the substrate 00. The barrier layer 50 is a second reflection control layer 42, that is, the barrier layer 50 has the function of reducing the reflection of ambient light by the display panel. The protective layer 60 is located at a side of the second reflection control layer 42 away from the substrate 00. In some embodiments of the present disclosure, the reflection control layer 40 includes the first reflection control layer 41 and the barrier layer 50, that is, the barrier layer 50 is reused as a part of the reflection control layer 40. In some embodiments of the present disclosure, the barrier layer 50 can block a path for the easily migrated dye in the first reflection control layer 41 to migrate to the protective layer 60, and the barrier layer 50 further has the function of reducing the reflectivity of the display panel.

In some embodiments of the present disclosure, the electronegativity of the barrier layer 50 is smaller than the electronegativity of the protective layer 60, so that the electron attraction capability of the protective layer 60 is relatively stronger, and the electron attraction capability of the barrier layer 50 is relatively weak. When the dielectric constant is used to characterize the size of the electronegativity, the dielectric constant of the barrier layer 50 is greater than the dielectric constant of the protective layer 60, and the interaction between the barrier layer 50 and the peripheral film layer is weak. When the dye in the reflection control layer 40 includes a cationic dye prone to migration, since the barrier layer 50 has a relatively weak electron attraction capability, the effect of the barrier layer 50 and the dye molecules in the reflection control layer 40 can be reduced. The barrier layer 50 is manufactured on the reflection control layer 40, blocking a path for the dye in the reflection control layer 40 to migrate to the protective layer 60, thereby achieving the stability of the anti-reflection performance of the reflection control layer 40, and avoiding failure of the reflection control layer 40 caused by optical abnormality due to migration of the dye.

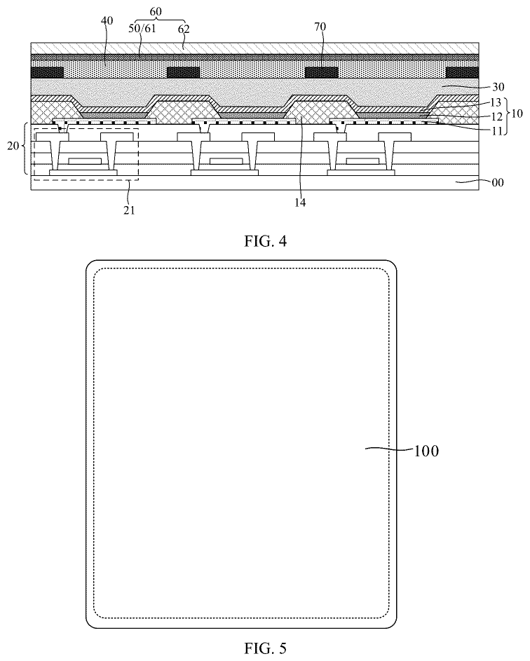

In some embodiments of the present disclosure, FIG. 4 is a cross-sectional view at a line A-A′ shown in FIG. 1 according to some embodiments of the present disclosure. As shown in FIG. 4, the display panel includes a barrier layer 50 located at a side of the reflection control layer 40 away from the substrate 00. The barrier layer 50 can provide a certain degree of protection for the reflection control layer 40, and the barrier layer 50 can serve as the first protective layer 61. The display panel further includes a second protective layer 62 located at a side of the barrier layer 50 away from the reflection control layer 40, and the barrier layer 50 and the second protective layer 62 together form a protective layer 60. That is, the barrier layer 50 is reused as a part of the protective layer 60. In some embodiments of the present disclosure, the barrier layer 50 can not only block the migration of the dye in the reflection control layer 40 to the second protective layer 62, but also can provide a certain degree of protection for the reflection control layer 40.

In some embodiments of the present disclosure, the barrier layer 50 includes an inorganic material. If the barrier layer 50 is made of the inorganic material, the barrier layer 50 can be made using a conventional film-forming process during manufacturing the display panel, and the manufacturing process is relatively simple. Moreover, it can be ensured that the interaction between the barrier layer 50 and the peripheral film layer is weak, so that the barrier layer 50 is used to block a path for the dye in the reflection control layer 40 to migrate to the protective layer 60.

In some embodiments of the present disclosure, the inorganic material in the barrier layer 50 includes silicon nitride. The silicon nitride has a relatively large dielectric constant, generally between 6 and 9. The barrier layer 50 made of silicon nitride can have a relatively high capacitance storage capability and a relatively low electronegativity, which can make the interaction between the barrier layer 50 and the peripheral film layer weaker. When the dye in the reflection control layer 40 includes the easily migrated dye, the barrier layer 50 can be used to block the dye in the reflection control layer 40 from migrating to the side of the protective layer 60, achieving the stability of the anti-reflection performance of the reflection control layer 40.

In some embodiments of the present disclosure, the inorganic material in the barrier layer 50 includes hafnium oxide. The dielectric constant of hafnium oxide is relatively large, generally between 20 and 25. The barrier layer 50 made of hafnium oxide can have a relatively high capacitance storage capability and a relatively low electronegativity, so that the barrier layer 50 can have a relatively weak interaction with the peripheral film layer. When the dye in the reflection control layer 40 includes the easily migrated dye, the barrier layer 50 can be used to block the dye in the reflection control layer 40 from migrating to the side of the protective layer 60, achieving the stability of the anti-reflection performance of the reflection control layer 40.

In some embodiments of the present disclosure, the barrier layer 50 may be manufactured by a chemical vapor deposition process, and process parameters may be adjusted during manufacturing. For example, the heat treatment temperature and time in the deposition film-forming process are reduced, or the film is formed using a low-temperature and high-pressure process, so that the prepared barrier layer 50 is relatively loose in structure, which facilitates reducing the electronegativity of the barrier layer 50, so that the prepared barrier layer 50 has a larger dielectric constant, the interaction between the barrier layer 50 and the peripheral film layer is weaker, and the barrier ability of the corresponding barrier layer 50 to dye migration in the reflection control layer 40 is stronger.

In some embodiments of the present disclosure, as shown in FIG. 2, the display panel further includes a light-blocking layer 70, and the light-blocking layer 70 is located at a side of the reflection control layer 40 adjacent to the encapsulation layer 30. The light-blocking layer 70 includes multiple openings V, and the openings V overlap the light-emitting elements 10 in a direction e perpendicular to a plane where the substrate 00 is located. As shown in FIG. 2, the display panel includes a pixel definition layer 14, and the light-blocking layer 70 overlaps the pixel definition layer 14. The arrangement of the light-blocking layer 70 can block the entry of ambient light between adjacent light-emitting elements 10, thereby preventing metal wires in a driving layer 20 from reflecting ambient light and preventing the metal from being visible. It can be understood that a pixel circuit 21 and some signal lines are arranged in the driving layer 20, and the light-blocking layer 70 can prevent the metal lines in the driving layer 20 from reflecting ambient light. The reflection control layer 40 can reduce ambient light from entering the display panel from a region corresponding to the light-emitting elements 10, thereby reducing reflection of ambient light by the region corresponding to the light-emitting elements 10, and the light-blocking layer 70 can reduce reflection of ambient light between adjacent light-emitting elements 10. In some embodiments of the present disclosure, the reflection control layer 40 and the light-blocking layer 70 cooperate to effectively reduce the reflectivity of the display panel and improve the overall display effect of the display panel.

In some embodiments of the present disclosure, the material of the light-blocking layer 70 may be, for example, a light-shielding material of black pigment, black dye, carbon black, or a combination thereof.

The present disclosure provides a method for manufacturing the display panel according to the embodiments of the present disclosure. First, a driving layer 20, multiple light-emitting elements 10 and an encapsulation layer 30 are sequentially fabricated at a substrate 00. A light-blocking layer 70 is fabricated at a side of the encapsulation layer 30 away from the substrate 00. The light-blocking layer 70 includes multiple openings V, and the openings V overlap the light-emitting elements 10 in a direction e perpendicular to a plane where the substrate 00 is located. Then, a reflection control layer 40 is fabricated using a film-forming process, and the reflection control layer 40 deposited in the openings V overlaps the light-emitting elements 10. A barrier layer 50 is fabricated using a film-forming process, and the barrier layer 50 covers the reflection control layer 40. A protective layer 60 is fabricated, and the protective layer 60 covers the barrier layer 50.

Based on the same inventive concept, the present disclosure further provides a display apparatus. FIG. 5 is a schematic diagram of a display apparatus according to some embodiments of the present disclosure. As shown in FIG. 5, the display apparatus includes the display panel 100 provided by any embodiment of the present disclosure. The structure of the display panel 100 has been described in the above embodiments and will not be elaborated here. The display apparatus provided by the embodiments of the present disclosure may be, for example, an electronic device having a display function, such as a mobile phone, a tablet, a computer, a television, a vehicle-mounted display, and a smart wearable product.

The above are merely exemplary embodiments of the present disclosure, which, as mentioned above, are not used to limit the present disclosure. Whatever within the principles of the present disclosure, including any modification, equivalent substitution, improvement, etc., shall fall into the protection scope of the present disclosure.

Finally, it should be noted that the technical solutions of the present disclosure are illustrated by the above embodiments, but not intended to limit thereto. Although the present disclosure has been described in detail with reference to the foregoing embodiments, those skilled in the art can understand that the present disclosure is not limited to the specific embodiments described herein, and can make various modifications, readjustments, and substitutions without departing from the scope of the present disclosure.

What is claimed is:

1. A display panel, comprising:
a substrate;
light-emitting elements located at a side of the substrate;
an encapsulation layer located at a side of the light-emitting elements away from the substrate;
a reflection control layer located at a side of the encapsulation layer away from the light-emitting elements; and
a barrier layer located at a side of the reflection control layer away from the encapsulation layer, wherein the barrier layer is in contact with the reflection control layer.

2. The display panel according to claim 1, wherein
a thickness of the barrier layer is defined as d, where d≤5000 Å.

3. The display panel according to claim 1, wherein
when a test frequency is 1 KMHz, a dielectric constant & of the barrier layer is greater than or equal to 5.

4. The display panel according to claim 1, wherein
a material of the barrier layer is different from a material of the reflection control layer.

5. The display panel according to claim 1, wherein
the barrier layer comprises an inorganic material.

6. The display panel according to claim 5, wherein
the inorganic material comprises silicon nitride or hafnium oxide.

7. The display panel according to claim 1, wherein a material of the barrier layer comprises an electronegative material or an electropositive material.

8. The display panel according to claim 1, wherein
an electronegativity of the barrier layer is smaller than an electronegativity of the reflection control layer.

9. The display panel according to claim 1, wherein
the barrier layer is reused as a part of the reflection control layer.

10. The display panel according to claim 1, further comprising a protective layer, the protective layer is located at a side of the barrier layer away from the reflection control layer.

11. The display panel according to claim 10, wherein
an electronegativity of the barrier layer is smaller than an electronegativity of the protective layer.

12. The display panel according to claim 10, wherein
the barrier layer is reused as a part of the protective layer.

13. The display panel according to claim 1, wherein
the reflection control layer comprises at least a dye and a base material.

14. The display panel according to claim 13, wherein
the dye comprises a cationic dye or an anionic dye.

15. The display panel according to claim 13, wherein
the base material comprises a resin.

16. The display panel according to claim 13, wherein
the reflection control layer further comprises a pigment.

17. The display panel according to claim 1, further comprising a light-blocking layer located at a side of the reflection control layer adjacent to the encapsulation layer, wherein the light-blocking layer comprises openings; and
in a direction perpendicular to a plane of the substrate, one of the openings overlaps a corresponding one of the light-emitting elements.

18. A display apparatus, comprising a display panel, wherein the display panel comprises:
a substrate;
light-emitting elements located at a side of the substrate;
an encapsulation layer located at a side of the light-emitting elements away from the substrate;
a reflection control layer located at a side of the encapsulation layer away from the light-emitting elements; and
a barrier layer located at a side of the reflection control layer away from the encapsulation layer, wherein the barrier layer is in contact with the reflection control layer.
